(19) United States
(12) Patent Application Publication
(10) Pub. No.: US 2026/0282810 A1
(43) Pub. Date: Sep. 17, 2026

(54) METHOD OF BONDING A DIE TO A DIE BONDING SITE IN THE PRESENCE OF A LIQUID AND A SYSTEM ADAPTED TO PERFORM THE METHOD

(71) Applicant: CANON KABUSHIKI KAISHA, Tokyo (JP)

(72) Inventor: Byung-Jin CHOI, Austin, TX (US)

(21) Appl. No.: 19/076,431

(22) Filed: Mar. 11, 2025

(51) Int. Cl. H01L 23/00; H01L 21/67

(52) U.S. Cl. CPC H10P 72/0446; H10W 72/07331; H10W 72/353

(57) ABSTRACT

A method can include dispensing a liquid onto a die bonding site of a substrate and modulating a die held by a die chuck and bringing the die into contact with the liquid. In an implementation, the method can further include bringing the die into contact with the liquid, while the peripheral edge of the die is not in contact with the die bonding site; and demodulating the die such that an outer region of the die is brought into contact with the die bonding site while a liquid is over a center of the die. In another implementation, bringing the die into contact with the liquid can cause a film to form, where the film becomes starved before the outer region of the die contacts the die bonding site. A system can be adapted to carry out the method.

### FIELD OF THE DISCLOSURE

The present disclosure relates to a method of bonding a die to a die bonding site in the presence of a liquid and a system adapted to perform the method.

### RELATED ART

Hybrid bonding is a technique to attach a die to a die bonding site of a bonding substrate. The die can be modulated so that a center along the bonding surface is extended away from a die chuck of a die bonding head. The center of the die contacts the die bonding site before other portions of the die. Upon or shortly thereafter contact, the bonding surface and the corresponding surface of the die bonding site are bonded. As more force is applied to the die, the die demodulates until substantially all of the bonding surface of the die contacts the die bonding site. The modulation-demodulation sequence can help to reduce the likelihood of air being trapped between the die and die bonding site during hybrid bonding.

### SUMMARY

In an aspect, a method can include dispensing a liquid onto a die bonding site of a substrate; modulating a die held by a die chuck such that the die bonding site is closer to a center of the die than a peripheral edge of the die; bringing the die into contact with the liquid, while the peripheral edge of the die is not in contact with the die bonding site; and demodulating the die such that an outer region of the die is brought into contact with the die bonding site such that the liquid is not present where the outer region overlaps and contacts the die bonding site.

In an implementation, along a major surface of the die, the peripheral edge of the die includes at least two edges.

In another implementation, the outer region includes a corner of the die.

In still another implementation, bringing the die into contact with the liquid causes a film to form that has a film area less than an area of the die.

In a further implementation, the liquid does not include an adhesive compound.

In another implementation, the liquid includes water, an alkyl alcohol having at most three carbon atoms, or a mixture of the water and the alkyl alcohol.

In still another implementation:

$${volume}_{liq} = film area * thickness , \qquad ( Equation 1 )$$

where volume_{liq} is a volume of the liquid dispensed, film area is in a range from 50% to 75% of an area of a major surface of the die, and thickness is in a range from 5 nm to 10 nm.

In a further implementation, demodulating the die is performed such that the outer region of the die is brought into contact with the die bonding site, and a portion of the liquid underlaps the center of the die when the outer region is in contact with the die bonding site.

In another aspect, a method can include dispensing a liquid onto a die bonding site of a substrate, wherein the liquid is a Newtonian fluid; modulating a die held by a die chuck such that the die bonding site is closer to a center of the die than a peripheral edge of the die; bringing the die into contact with the liquid, while the peripheral edge of the die is not in contact with the die bonding site; and demodulating the die, wherein, during at least a portion of demodulating the die, at least a portion of the liquid exhibits non-Newtonian behavior.

In an implementation, during initial contact of the die with the liquid, the liquid exhibits Newtonian behavior.

In another implementation, during demodulating, at least a portion of the liquid between the die and the die bonding site has a thickness of at most 5 nm.

In still another implementation, the liquid includes water, an alkyl alcohol having at most three carbon atoms, or a mixture of the water and the alkyl alcohol.

In a further implementation, the liquid does not contact at least one corner of the die during dispensing the liquid, modulating the die, and demodulating the die.

In another implementation, demodulating the die is performed such that the outer region of the die is brought into contact with the die bonding site, and a portion of the liquid underlaps the center of the die when the outer region is in contact with the die bonding site.

In a further aspect, a method can include dispensing a liquid onto a die bonding site of a substrate; modulating a die held by a die chuck such that the die bonding site is closer to a center of the die than a peripheral edge of the die; bringing the die into contact with the liquid, wherein bringing the die into contact with the liquid causes a film to form; and demodulating the die such that at least a portion of the film becomes starved and does not flow to an outer region of the die.

In an implementation:

$${volume}_{liq} = area * thickness \qquad ( Equation 1 )$$

where volume_{liq} is a volume of the liquid dispensed, area is in a range from 50% to 75% of a major surface of the die, and thickness is in a range from 5 nm to 10 nm.

In another implementation, the liquid includes water, an alkyl alcohol having at most three carbon atoms, or a mixture of the water and the alkyl alcohol.

In a further implementation, demodulating the die is performed such that at least a portion of the peripheral edge of the of the die is brought into contact with the die bonding site, and a portion of the liquid underlaps the center of the die when the outer region is in contact with the die bonding site.

In another aspect, a system can include a liquid dispense head and a die chuck. The system can be adapted to dispense a liquid from the liquid dispense head onto a die bonding site of a substrate; modulate a die held by the die chuck such that the die bonding site is closer to a center of the die than a peripheral edge of the die; bring the die into contact with the liquid, while the peripheral edge of the die is not in contact with the die bonding site; and demodulate the die such that an outer region of the die is brought into contact with the die bonding site such that the liquid is not present where the outer region overlaps and contacts the die bonding site.

In a further aspect, a method of manufacturing a plurality of electronic devices can include dispensing a liquid onto die bonding sites of a substrate; modulating dies held by die chucks such that the die bonding sites are closer to centers of the dies than peripheral edges of the dies; bringing the dies into contact with the liquid, while the peripheral edges of the dies are not in contact with the die bonding sites; demodulating the dies such that outer regions of the dies are brought into contact with the die bonding sites such that the liquid is not present where the outer regions overlap and contact the die bonding sites; and dicing the substrate to form individual electron devices, wherein dicing is performed after demodulating the dies.

### BRIEF DESCRIPTION OF THE DRAWINGS

Implementations are illustrated by way of example and are not limited in the accompanying figures.

FIG. 1 includes a plot of distortion error between a die and die bonding site when a modulation-demodulation sequence is performed during hybrid bonding when a liquid is not present between the die and the die bonding site.

FIG. 2 includes a conceptual view of a portion of a system that includes a liquid dispense apparatus.

FIG. 3 includes a side view of another portion of the system, wherein the other portion includes a die bonding apparatus.

FIGS. 4 and 5 include a process flow diagram for a hybrid bonding process using the system of FIGS. 2 and 3.

FIG. 6 includes an illustration of a cross-sectional view of a bonding substrate and a substrate chuck while droplets of a liquid are dispensed over a portion of the bonding substrate.

FIG. 7 includes an illustration of a cross-sectional view of the bonding substrate and the substrate chuck after dispensing the droplets of the liquid.

FIG. 8 includes an illustration of a side view of a portion of the die bonding apparatus of FIG. 3 and further including a set of dies coupled to an array of bonding heads and the bonding substrate coupled to a substrate chuck.

FIG. 9 includes an illustration of a cross-sectional view of a die chuck and a particular die from the set of dies in FIG. 8 before the particular die is modulated.

FIG. 10 includes an illustration of a side view of the die bonding apparatus, the set of dies, and the bonding substrate of FIG. 8 after moving the set of dies over corresponding die bonding sites of the bonding substrate.

FIG. 11 includes an illustration of a cross-sectional view of a die chuck and the die in FIG. 10 during a time when a particular die of the set of dies is modulated.

FIG. 12 includes an illustration of a cross-sectional view of the die chuck, the particular die in FIG. 11, the bonding substrate, and the droplets of the liquid over a die bonding site of the bonding substrate when the die initially contacts the droplets.

FIG. 13 includes an illustration of a cross-sectional view of the die chuck, the die, the bonding substrate, and the droplet of FIG. 12 as the droplets coalesce and the liquid spreads along the surface of a portion of the bonding substrate.

FIG. 14 includes an illustration of a cross-sectional view of the die chuck, the die, the bonding substrate, and the liquid of FIG. 13 when the corners of the die contact and become bonded to the die bonding site of the bonding substrate.

FIG. 15 includes an illustration of a cross-sectional view of the die, the bonding substrate, and the liquid of FIG. 14 after the die chuck is decoupled from the particular die.

FIG. 16 includes an illustration of a side view of the die bonding apparatus of FIG. 10 after the set of dies are bonded to die bonding sites of the bonding substrate.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

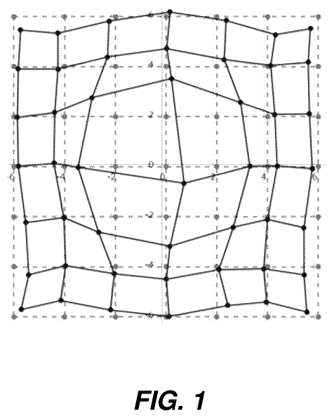

Some methods of hybrid bonding may use a modulation-demodulation sequence during a bonding operation that can result in distortion error. FIG. 1 includes a plot that illustrates the distortion error. In FIG. 1, the dashed lines and points between the dished lines represent where the die should be attached to the surface of the die bonding site. The solid lines and points between the solid line show where die contacts the die bonding site. Many points on the die are offset from their desired corresponding points on the die bonding site. The central portion of the bonding surface of the die is substantially more distorted as compared to the outer regions of the die. Hybrid bonding has small dimensional tolerances to ensure proper electrical connection between the die and its corresponding die bonding site. The modulation-demodulation sequence can result in poor electrical contact between the die and the bonding substrate at the die bonding site.

In an attempt to address the problem, some artisans put a thin layer of liquid between the die and the die bonding site. The liquid extends beyond all of the peripheral edges of the die before the die is bonded to the die bonding site. Thus, the die does not contact and is spaced apart from the die bonding site by the liquid. The die and die bonding site may move relative to each other before the bonding occurs. The motion may result in the die not being bonding at its desired location. A thin layer of an adhesive compound may be present between bond pads of the die and bond pads of the die bonding site and can adversely affect contact resistance between the bond pads. A need exists for hybrid bonding to be performed without significant distortion error and movement due to a liquid being present between the die and die bonding site during hybrid bonding.

Distortion and alignment issues can be addressed by bonding a die to a die bonding site of a bonding substrate while a liquid is present between the die and the bonding substrate. The liquid can help dampen vibration or other noise that may interfere with alignment between the die and its corresponding die bonding site of the bonding substrate. The amount of liquid and its location on the die bonding site can be selected such that the liquid is starved during demodulation of the die so that an outer region of the die physically contacts the die bonding site when bonding the die to the die bonding site while at least a portion of the liquid is present over the center of the die bonding site. The outer region can include at least two edges that can meet at a corner of the die. The amount of distortion between the die and its corresponding die bonding site can be substantially less than if no liquid would have been present. The method may have less misalignment as compared to a conventional method where the liquid is present between all of the die and die bonding site before the die is bonded to the die bonding site.

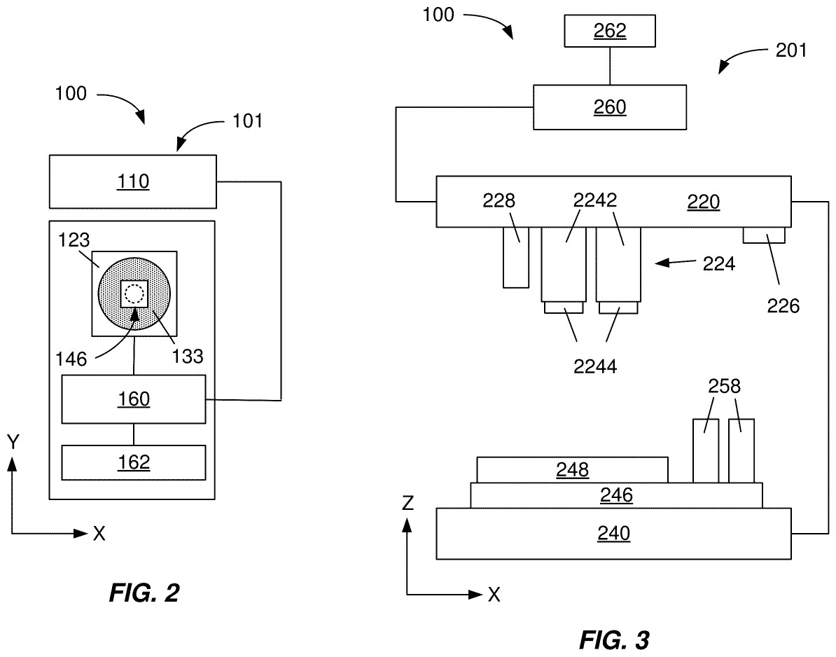

A system 100 illustrated in FIGS. 2 and 3 can be used for a method of hybrid bonding dies to die bonding sites of a bonding substrate. The system 100 can include a liquid dispense apparatus 101 in FIG. 2 and a die bonding apparatus 201 in FIG. 3. The liquid dispense apparatus 101 can include a substrate transfer tool 110, a liquid dispense station 123, a controller 160, and a memory 162. The die bonding apparatus 201 can include a bridge 220, components coupled to the bridge 220, a base 240, components coupled to the base 240, a controller 260, and a memory 262.

In the system 100, the components and functions provided by the liquid dispense apparatus 101 and the die bonding apparatus 201 may be combined into one apparatus or may be distributed among more than two apparatuses. Components within the system 100 are described in more detail below. Components that provide similar functionality, such as the controllers 160 and 260, are addressed together in the description below.

Referring to FIG. 2, the substrate transfer tool 110 can be adapted to transfer a bonding substrate to or from any of a substrate pod (not illustrated), the liquid dispense station 123, the die bonding apparatus 201, or other equipment. The substrate transfer tool 110 may include one or more components of an Equipment Front End Module (EFEM). The components of the EFEM can include one or more of each of the following: a robot arm, a robot hand adapted for holding substrates, a sensor, a motor for moving the robot arm, another motor for moving the robot arm, or another component that can be used in transferring or to support a transfer operation of a substrate. The robot arm can be adapted to move the substrate with or without droplets of a liquid or a layer between different parts of the system 100, for example, to or from a substrate chuck 133 in the liquid dispense station 123 and a substrate chuck 248 in the die bonding apparatus 201 in FIG. 3. In another implementation, more than one substrate transfer tool may be used. For example, each of the liquid dispense apparatus 101 and the die bonding apparatus 201 may have its own substrate transfer tool.

The substrate pod can hold a plurality of workpieces. An example of a substrate pod is a Front Opening Unified Pod (FOUP) which is defined by industry standards (for example, SEMI E47.1-1106, 2012) as a pod for storing and transporting workpieces. The apparatuses described herein can include coupling plates, interface holes, and load ports for receiving and transferring substrates to and from one to four substrate pods. A workpiece can be removed from the substrate pod, processed within the liquid dispense apparatus 101 or the die bonding apparatus 201, or another substrate pod when the die bonding operation is completed.

The liquid dispense station 123 can be adapted to receive the bonding substrate (not illustrated in FIGS. 2 and 3) from the substrate transfer tool 110 and dispense a liquid over the bonding substrate. The liquid dispense station 123 can include the substrate chuck 133 and a liquid dispense head 146.

In addition to the substrate chuck 133 of the liquid dispense apparatus 101, the die bonding apparatus 201 includes the substrate chuck 248. Either or both of the chucks 133 and 248 can be a vacuum chuck, a pin-type chuck, a groove-type chuck, an electrostatic chuck, an electromagnetic chuck, or another suitable component that can retain a substrate. In an implementation, either or both of the chucks 133 and 248 can be heated, cooled, or both heated and cooled. In the same or different implementation, a fluid (not illustrated) can flow through either or both of the chucks 133 and 248 to increase or decrease the temperature of the such chuck(s).

The liquid dispense head 146 can be adapted to dispense a liquid over a bonding substrate when the bonding substrate is over a substrate chuck 133. The liquid dispense head 146 can include at least one nozzle that dispenses the liquid. The dashed line within the liquid dispense head 146 is used to indicate that the liquid is dispensed along the bottom side of the liquid dispense head 146. A positioning stage (not illustrated in FIG. 2) can be coupled to the substrate chuck 133, and the positioning stage, the liquid dispense head 146, or both can be adapted to move when dispensing the liquid.

Referring to FIGS. 2 and 3, the system 100 can include a controller 160 in the liquid dispense apparatus 101 and a controller 260 in the die bonding apparatus 201. The controller 160 can control components within the liquid dispense apparatus 101. The controller 160 can be coupled to the substrate transfer tool 110, the dispense station 123, the substrate chuck 133, the liquid dispense head 146, and the memory 162. The controller 260 can control components within the die bonding apparatus 201. The controller 260 can be coupled to the bridge 220, any component coupled to the bridge 220, the base 240, any component coupled to the base 240, and the memory 262.

The controller 160 can operate using a computer readable program, optionally stored in memory 162, and the controller 260 can operate using a computer readable program, optionally stored in memory 262. Either or both of the controllers 160 and 260 can include a processor (for example, a central processing unit of a microprocessor or microcontroller), a field-programmable gate array (FPGA), an application specific integrated circuit (ASIC), or another electrical component adapted to carry out instructions in hardware, software, or firmware. Either or both of the controllers 160 and 260 can further include internal memory, such as a set of registers, a cache memory, a flash memory, or another type of memory. Either or both of the controllers 160 and 260 can be within their corresponding apparatuses as illustrated in FIGS. 2 and 3. In another implementation (not illustrated) of the die bonding system 100, either or both of the controllers 160 and 260 can be at least part of a computer external to the die bonding system 100, where such computer is bidirectionally coupled to the die bonding system 100. Either or both of the controllers 160 and 260 can include one processor or a plurality of processors that communicate over a bus, a local area intranet, or a wide area internet.

The memory 162 can include a non-transitory computer readable medium that includes instructions to carry out the actions associated with a liquid dispense operation. The memory 262 can include a non-transitory computer readable medium that includes instructions to carry out the actions associated with a die bonding operation. Either or both of the memories 162 and 262 can include a set of registers, a cache memory, a flash memory, a hard drive, or another memory. Either or both of the memories 162 and 262 can further include data tables that can be accessed by either or both of the controllers 160 and 260 to assist in determining an operating parameter, for example, parameters used in dispensing the liquid within the liquid dispense station 123, bonding a die to a bonding substrate within the die bonding apparatus 201, or both used in the methods as described below.

More or fewer controllers and more or fewer memories may be used with respect to the system 100. In another implementation, a single controller can perform all of the functions described with respect to the controllers 160 and 260. Thus, one controller, rather than two controllers, may be used with the system 100. In a further implementation, the controller 160 may control the liquid dispense apparatus 101 and die bonding apparatus 201, and thus the controller 260 is not required, or the controller 260 may control the liquid dispense apparatus 101 and die bonding apparatus 201, and thus the controller 160 is not required. In another implementation, a single memory or more than two memories may be used with the system 100.

Turning to the die bonding apparatus 201 in FIG. 3, the bridge 220 can be coupled to an array of bonding heads 224, a reference 226 having one or more alignment marks, and registration hardware 228. The base 240 can be coupled to a carriage 246. Although not illustrated, the die bonding apparatus 201 may include die transfer seats (for example, pick-up heads, part of a pick-and-place tool, etc.) that can be used to transfer dies to the array of bonding heads 224. The die bonding apparatus 201 may optionally further include a source chuck (not illustrated) coupled to the bridge 220, where the source chuck can be used to hold a source substrate that includes dies to be bonded to a bonding substrate.

The bridge 220, the base 240, and components physically between the bridge 220 or the base 240 can be organized along an X-direction, a Y-direction, a Z-direction, or a combination thereof. With respect to cross-sectional or side views, the X-direction is between the left-hand and right-hand sides of the drawings, the Z-direction is between the top and bottom of the drawings, and the Y-direction is into and out of the drawing sheet.

The array of bonding heads 224 can be arranged as a vector (a row or a column of bonding heads) or as a matrix (at least two rows and at least two columns of bonding heads). Regarding the matrix, the number of bonding heads within the array of bonding heads 224 may be different between rows, between columns, or between rows and columns. Some array configurations can include 3×1, 6×1, 2×2, 2×3, 2×4, 4×2 10×10, or another rectangular shape, where the first number corresponds to the number of bonding heads along a row or column, and the second number corresponds to the number of bonding heads along the other of the row or column. In theory, dies from an entire wafer may be transferred during a single transfer cycle. For such a configuration, from a bottom view, the array of bonding heads 224 may have fewer bonding heads along rows closer to the top and bottom of the array as compared to the row or the pair of rows closest to the center of the array, and the array of bonding heads 224 may have fewer bonding heads along columns closer to the left-hand side and right-hand side of the array as compared to the column or the pair of columns closest to the center of the array. After reading this specification, skilled artisans will be able to determine an arrangement for the array of bonding heads 224 that meets the needs or desires for a particular application.

Any or all of the bonding heads within the array of bonding heads 224 can include a bonding head body 2242. The bonding head body 2242 can be coupled to a die chuck 2244 within a die chuck retention zone along a bottom surface of the bonding head body 2242. The die chuck 2244 can be a vacuum chuck, a pin-type chuck, a groove-type chuck, an electrostatic chuck, an electromagnetic chuck, or a Bernoulli chuck. The die chuck 2244 can be adapted to modulate the shape of a die during a die bonding sequence.

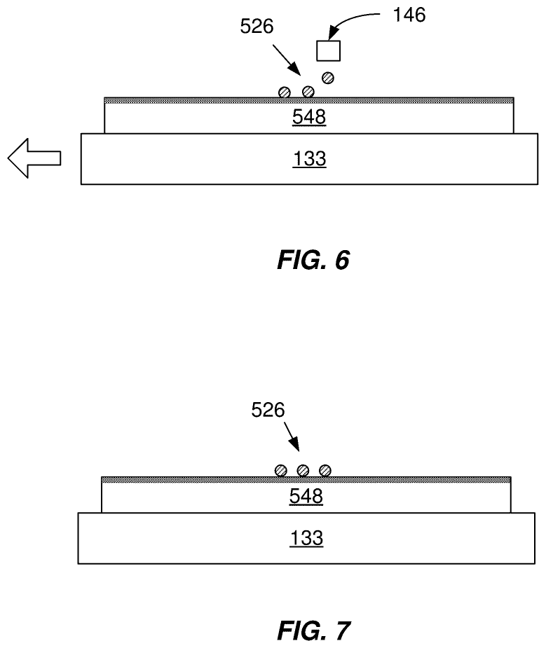

Registration hardware 228 is coupled to the bridge 220. The registration hardware 228 can include an optical component and provide information to the controller 260 or a local controller located within the registration hardware 228, the bridge 220, the base 240 or a component coupled to the bridge 220, the base 240, or a combination thereof. The information from the registration hardware 228 can be used to determine a bonding pitch for the die bonding sites of a bonding substrate 548 (illustrated in FIG. 6). Further, the information may be used to identify or confirm the bonding substrate 548 is the correct substrate to which dies will be bonded and the position of bonding sites for those dies on the bonding substrate 548.

The carriage 246 is coupled to the base 240. The carriage 246 can be a positioning stage and adapted to provide translating motion along the base 240 in the X-direction, Y-direction, or Z-direction or rotational motion about one or more of axes, such as rotation about a Z-axis and along a plane lying along the X-direction and Y-direction. The carriage 246 can be coupled to the substrate chuck 248 and registration hardware 258. The substrate chuck 248 was described earlier in this specification with the substrate chuck 133.

The registration hardware 258 can include an optical component and provide information to the controller 260 or a local controller located within the registration hardware 258, the base 240, or a component coupled to the bridge 220, the base 240, or a combination thereof. The optical component can include a lens that is optically coupled to a mirror, a prism, a grating, a light source, a fiber optic cable, an aperture, a tube, a camera, or a combination thereof. The information from the registration hardware 258 can be used to confirm the presence of one or more dies (not illustrated in FIG. 3), to adjust positions of the die chucks 2244, or confirm that any one or more of die chucks within the array of die chucks 224 are at or near (within a tolerance) their proper positions. Further, the information may be used to identify or confirm the set of dies includes the correct dies to be bonded to die bonding sites on the bonding substrate and the position of the set of dies with respect to their corresponding die bonding sites.

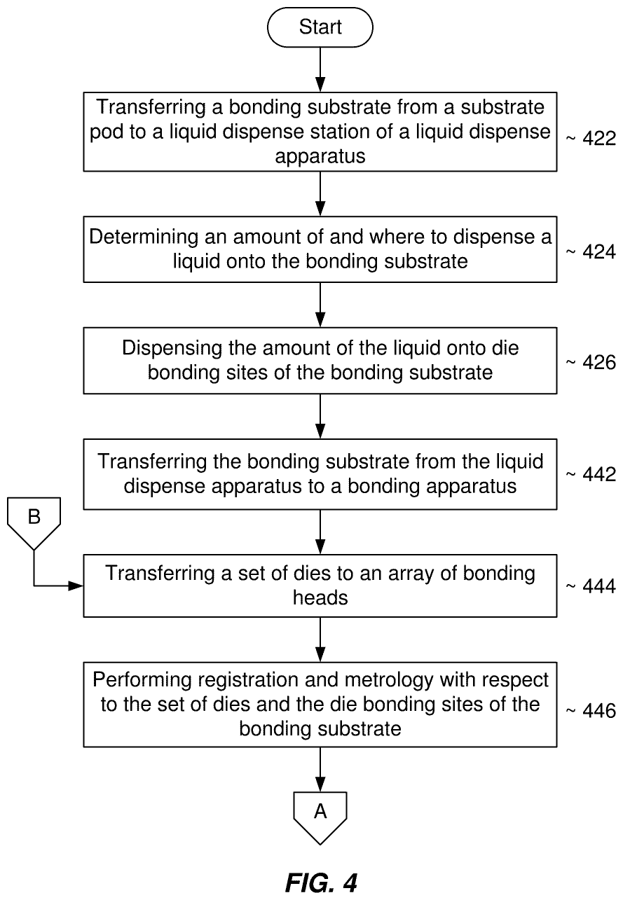

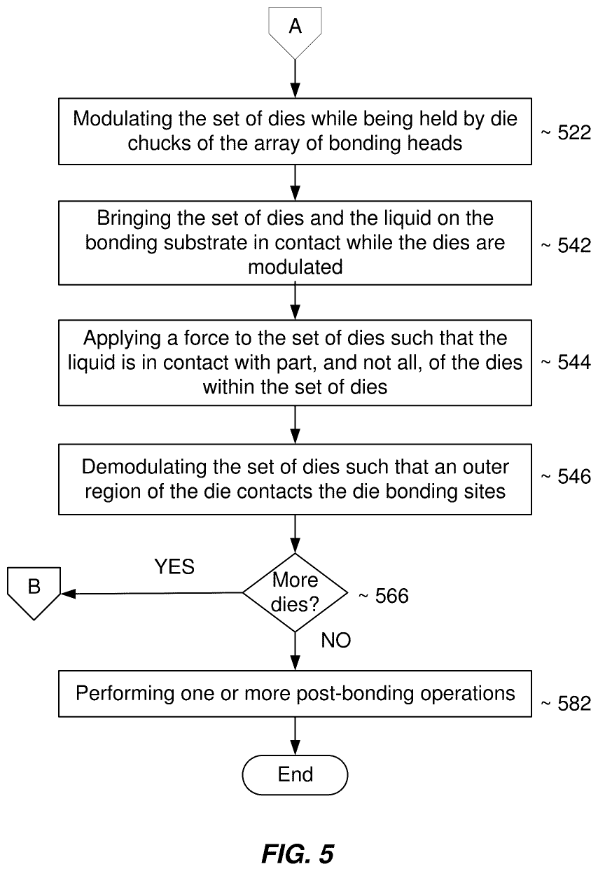

Attention is directed to methods of using the system 100 when dispensing liquid onto a bonding substrate and bonding one or more dies to corresponding bonding site(s) on the bonding substrate. FIGS. 4 and 5 include a process flow diagram of a method that is described with respect to FIGS. 6 to 16. Some of the figures will be described with respect to a particular die within a set of dies and a particular bonding head within the array of bonding heads 224 to simplify understanding of the methods. Such description also applies to the other dies within the set of dies and the other bonding heads within the array of bonding heads 224. The methods will be described in reference to the system 100 and its components as illustrated in FIGS. 2 and 3 unless explicitly stated to the contrary. After reading this specification, skilled artisans will appreciate that the methods can be used with respect to other apparatuses having other bonding heads as described herein with little or no modification to the methods.

The method can include transferring a bonding substrate from a substrate pod to a liquid dispense station of a liquid dispense apparatus at block 422 in FIG. 4. Referring to FIGS. 2 and 6, the substrate transfer tool 110 can obtain a bonding substrate 548 from a substrate pod or another piece of equipment where the bonding substrate 548 is located. Before transferring the bonding substrate 548, the bonding substrate 548 can have an activated surface (illustrated with a dark band) to aid in bonding. A surface can be activated by exposing the surface to a plasma treatment and deionized water rinse to hydrate the surface. Where reasonably practical, contact with an activated surface before bonding should be avoided. The controller 160 or a local controller can transmit a signal for the substrate transfer tool 110 to position the bonding substrate 548 within a tolerance of its desired position over the substrate chuck 133 within the liquid dispense station 123. The tolerance may be within 5 mm, within 1 mm, within 500 microns, 200 microns, within 90 microns, or within 50 microns of the desired position.

The controller 160 or a local controller may or may not transmit a signal to the substrate chuck 133 or a stage coupled to the substrate chuck 133 to move during the positioning operation. After the bonding substrate 548 is at the desired position or within a tolerance of the desired position, the controller 160 or a local controller can transmit a signal to activate a valve or switch used to activate a holding mechanism for the substrate chuck 133. For example, the valve may be activated so that a vacuum source pulls a vacuum between the bonding substrate 548 and the substrate chuck 133. In another example, the switch may be activated to allow current to flow through a circuit for an electromagnetic or electrostatic element that can hold the bonding substrate 548 and substrate chuck 133 in place relative to each other.

The method can further include determining an amount of and where to dispense a liquid onto the bonding substrate at block 424 in FIG. 4. The controller 160 or a local controller may have access to information regarding the bonding substrate 548. The information can include the amount of the liquid that is to be dispensed on the die bonding sites for the bonding substrate 548.

The amount of liquid is selected such that during die bonding, the liquid becomes starved allowing one or more of the corners of a die to physically contact the activated surface at the die bonding site of the bonding substrate 548 while a portion of the liquid underlaps a center of the die. In other terms, during die bonding, droplets of the liquid can coalesce if this has not already occurred to form a liquid film, and the liquid film spreads starting from close to the center of the die outward but eventually stops spreading when the liquid film thickness gets too thin. At a certain point, as the thickness of the liquid film is sufficiently thin, the shear stress increases and slows down the spreading front velocity of the liquid film while the velocity of the die-to-die bonding site conforming front during demodulation is greater than the liquid spreading velocity. Such a velocity difference can cause the boundary of the die-to-die bonding site contact at locations at an outer region of the die, such as closer corners of the die as compared to the center of the die, where such outer region can be starved of the liquid film. In a non-limiting example, the volume of the liquid to be dispensed can be calculated using Equation 1.

$${volume}_{liq} = film area * thickness \qquad ( Equation 1 )$$

volume_{liq} is a volume of the liquid dispensed,
film area is in a range from 50% to 75% of an area along a major surface of the die to be bonded to the bonding substrate 548, and
thickness is in a range from 5 nm to 10 nm.

The liquid can be Newtonian fluid at a macroscopic level, where the macroscopic level refers to a thickness of the liquid that is significantly thicker than 10 nm. As the liquid becomes starved, the liquid can exhibit non-Newtonian behavior. In an implementation, when the thickness of the liquid is approximately 10 nm or less, the liquid may behave like a solid, and the liquid no longer flows. The liquid can be water, an alkyl alcohol having at most three carbon atoms (for example methyl alcohol, ethyl alcohol, n-propyl alcohol, isopropyl alcohol, etc.), or a mixture of water and the alkyl alcohol. The liquid is a non-adhesive which can be confined during the bonding process and then subsequently removed through porous layers or incorporated into the bonded structures.

In an implementation, the liquid may not be an adhesive compound. An adhesive compound would interfere with the electrical and thermal performance of a hybrid bonded device. The liquid is selected such that it is removed from the bonding interface before, after, or during subsequent annealing that is performed after the initial hybrid bonding step.

The information may include information regarding locations of the die bonding sites for the bonding substrate 548. Such information may be provided in a site map for the bonding substrate 548 or a part number or other identifier for dies on the bonding substrate 548.

Determining the amount and where the liquid is to be dispensed can be performed by the controller 160 or a local controller. If data used in determining the amount and where the liquid is to be dispensed is not in memory within the controller 160 or a local controller, such data may be within the memory 162, the memory 262 or may be obtained from a memory outside the system 100.

The method can include dispensing the amount of the liquid onto die bonding sites of the bonding substrate at block 426 in FIG. 4. The information regarding the amount of liquid (for example, Equation 1 above) and where the liquid is to be dispensed in block 424 can be used by the controller 160 or local controller that can transmit a signal for the liquid dispense head 146 to dispense droplets of the liquid 526 at desired location(s) on the bonding substrate 548 as illustrated in FIG. 6. Referring to FIGS. 2 and 6, when the droplets of the liquid 526 are being dispensed, (1) a carriage or a moving platform can move the substrate chuck 133 as illustrated in FIG. 6, (2) the liquid dispense head 146 can move (not illustrated), or both (1) and (2). After the droplets of the liquid 526 are dispensed as illustrated in FIG. 7, the droplets can be near centers of die bonding sites along the exposed surface of the bonding substrate 548. The droplets may be spaced apart from peripheral edges of the die bonding sites so that corners of dies can be bonded where the dies and corresponding die bonding sites will physically contact one another. Some or all of the droplets of the liquid 526 may or may not coalesce before a die contacts the liquid 526.

The method can include transferring the bonding substrate from the liquid dispense apparatus to a bonding apparatus at block 442 in FIG. 4. Referring to FIGS. 2, 3, 7, and 8, the controller 160 or a local controller can deactivate a valve or switch so that the bonding substrate 548 is no longer held by the substrate chuck 133. The controller 160 or a local controller can transmit a signal for the substrate transfer tool 110 to move the bonding substrate 548 from the substrate chuck 133 to the substrate chuck 248. More than one substrate transfer tool may be used during the transfer. Further, the bonding substrate 548 may or may not be placed into a substrate pod that is moved from the liquid dispense apparatus 101 to the die bonding apparatus 201. The die bonding apparatus 201 may have its own substrate transfer tool that transfers the bonding substrate 548 from the substrate pod to the substrate chuck 248. Care may be exercised to ensure the liquid 526 on the bonding substrate 548 does not move to an undesired location, such as a location where a corner of a die is to contact a die bonding site. In an alternative implementation, the transferring step in block 442 is not performed and the dispensing in block 426 is performed on the substrate chuck 248.

The controller 260 or a local controller may transmit a signal to the substrate chuck 248 or the carriage 246 coupled to the substrate chuck 248 to move during the positioning operation. After the bonding substrate 548 is at the desired position or within a tolerance of the desired position, the controller 260 or a local controller can transmit a signal to activate a valve or switch used to activate a holding mechanism for the substrate chuck 248. For example, the valve may be activated so that a vacuum source pulls a vacuum between the bonding substrate 548 and the substrate chuck 248. In another example, the switch may be activated to allow current to flow through a circuit for an electromagnetic or electrostatic element that can hold the bonding substrate 548 and substrate chuck 248 in place relative to each other.

The method can include transferring a set of dies to an array of bonding heads at block 444 in FIG. 4. Referring to FIG. 8, a set of dies 722 can be transferred from an array of die transfer seats (not illustrated) or a pick-and-place tool to the array of bonding heads 224. If needed or desired, the registration hardware 228 can be used to confirm the array of die transfer seats is properly positioned with respect to the array of bonding heads 224. The controller 260 or a local controller can transmit a signal for the die transfer seats within the array of die transfer seats to be extended toward the bonding heads within the array of bonding heads 224, for the bonding heads within the array of bonding heads 224 to be extended toward the die transfer seats within the array of die transfer seats, or both. The dark bands along the set of dies 722 represent activated surfaces to assist in bonding the set of dies 722 to the bonding substrate 548. In a non-limiting implementation, the activated surfaces can be hydrolyzed surfaces of a silicon oxide material. The droplets of liquid 526 in FIG. 7 are present along the surface of the bonding substrate 548 but are not illustrated due to the scale of the illustration in FIG. 8.

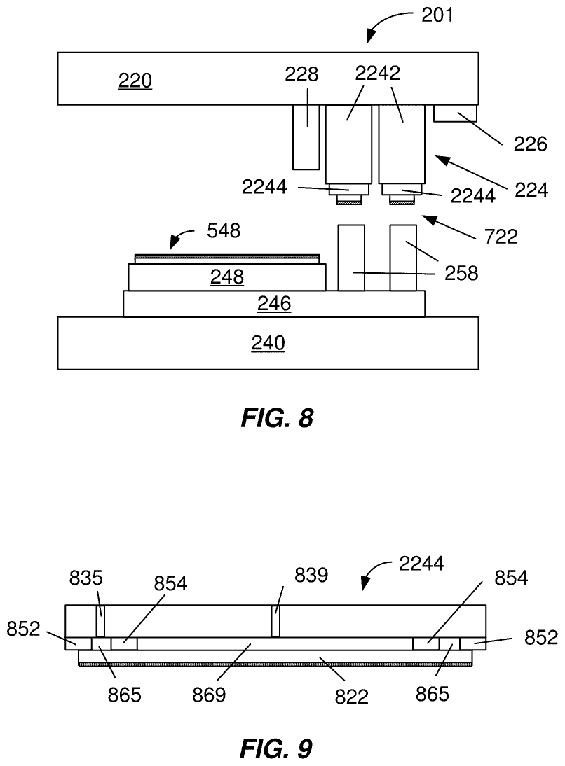

FIG. 8 includes the set of dies 722 after being transferred from the array of die transfer seats to the array of bonding heads 224. Each of the dies within the set of dies 722 may or may not be a chiplet and can include an electrical component, such as a transistor or a capacitor, or a circuit. The electrical component or circuit can be within a microprocessor, a microcontroller, a graphic processing unit, a digital signal processor, a memory die (for example, a Level 2 or Level 3 cache, a flash memory, or another memory), a power transistor die, a power circuit die, a capacitor, or an interposer. The die can be a small block of semiconducting material on which a given functional circuit is fabricated. The die can include a set of electronic components and circuits formed on it by patterning, coating, etching, doping, plating, singulating, etc. The die can have electrical functions, such as any of the following: memory; logic; field-programmable gate arrays (FPGA); accelerator circuits; application-specific integrated circuits (ASICs); security co-processors; graphics-processing units (GPUs); machine-learning circuits; specialized processors; controllers; devices; electrical circuits; arrays of passive components; etc. The die can also be or include a micro-electromechanical systems (MEMS) device; an optical device; an electrical-optical device; a microfluidic device; a piezoelectric device; a thermoelectric device; a spintronic device; a superconducting device; etc. The dies within the set of dies 722 may be substantially identical to each other or may include different types of dies. FIG. 9 includes a particular die 822 from the set of dies 722.

Referring to FIGS. 3, 8, and 9, the controller 260 or a local controller can transmit a signal for a pressure actuator for a bonding head within the bonding head to activate the pressure actuator to evacuate a flow channel 835 and a zone 865 that is defined by lands 852 and 854 of the die chuck 2244. The vacuum within the zone 865 can be sufficient to hold the particular die 822. A flow channel 839 and a zone 869 can be at or near ambient pressure or be evacuated similar to the flow channel 835 and zone 865. The controller 260 or local controller may or may not transmit a signal to activate a pressure actuator for the flow channel 839 and the zone 869 to achieve the desired pressure (vacuum or at or near ambient pressure).

The method can further include performing registration and metrology with respect to the set of dies and the die bonding sites of the bonding substrate at block 446 in FIG. 4. The registration hardware 228 can obtain information regarding the bonding substrate 548, and the registration hardware 258 can obtain information regarding the set of dies 722. The controller 260 or a local controller can receive signals from the registration hardware 228 regarding information on the bonding substrate 548. The signals can include information that may or may not correspond with part number(s) for the bonding substrate 548. Such information can be used to confirm that the correct bonding substrate 548 is coupled to the substrate chuck 248. If the information includes the part number, the controller 260 or local controller can obtain from the memory 262 or another memory further information regarding the bonding substrate 548, such as areas and locations of die bonding sites of the bonding substrate 548 where the set of dies 722 will be bonded to the bonding substrate 548, sizes, locations, or both sizes and locations of bonding pads for the bonding substrate 548, or other information regarding the physical layout of the bonding substrate 548 based on the design of the bonding substrate 548. Thus, the areal dimensions, locations, or other information regarding the physical layout of the bonding substrate 548 can represent design values, and not actual values, for the parameters. The design information is not required for all implementations, and thus, obtaining the design information may not be performed.

Alternative, or in addition to the design values, the information for actual values for areas and locations of die bonding sites of the bonding substrate 548 where the set of dies 722 will be bonded to the bonding substrate 548, sizes, locations, or both sizes and locations of bonding pads for the bonding substrate 548, or other information regarding the physical layout of the bonding substrate 548 can be determined by the controller 260 or a local controller based at least in part on signals transmitted by the registration hardware 228 and received by the controller 260 or a local controller.

The controller 260 or a local controller can receive signals from the registration hardware 258 regarding information the set of dies 722. The signals can include information that may or may not correspond part number(s) for the set of dies 722. Such information can be used to confirm that the correct dies will be bonded to the bonding substrate 548. If the information includes part number(s), the controller 260 or local controller can obtain from the memory 262 or another memory further information regarding the set of dies 722, such as areal dimensions of dies within the dies 722, locations of bonding pads within the dies for the set of dies 722, sizes of bonding pads for the set of dies 722, or other information regarding the physical layout of the set of dies 722 based on the designs of the set of dies 722. Thus, the areal dimensions, locations, or other information regarding the physical layout of the set of dies 722 can represent design values, and not actual values, for the parameters. The design information may or may not assist in more quickly performing the registration or metrology. The design information is not required for all implementations, and thus, obtaining the design information may not be performed.

Alternative, or in addition to the design values, the information for actual values for areal dimensions of the dies 722, locations of bonding pads within the dies for the set of dies 722, sizes of bonding pads for the set of dies 722, or other information regarding the physical layout of the set of dies 722 can be determined by the controller 260 or a local controller based at least in part on signals transmitted by the registration hardware 228 and received by the controller 260 or a local controller.

The controller 260 or a local controller can use the information generated from the signals from the registration hardware 228 and 258 to determine whether the relative positions of the die bonding sites within the bonding substrate 548 and the set of dies 722 are within tolerance. If the relative positions are not within tolerance, (1) the positions of the dies within the set of dies 722 can be adjusted, (2) the position of the die bonding sites of the bonding substrate 548 can be adjusted, or both (1) and (2) such that their relative positions are within tolerance. If the relative positions between the dies and the die bonding site were within tolerance, the adjustment is not required; however, an adjustment may be performed to reduce further alignment error between the dies and the die bonding sites.

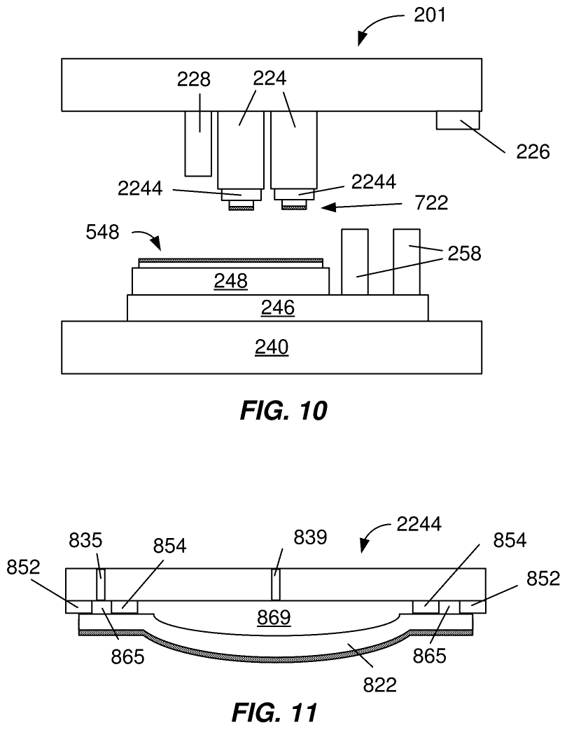

The bonding substrate 548, the set of dies 722, or both may be moved so that the set of dies 722 is over corresponding die bonding sites of the bonding substrate 548. In a non-limiting example, the controller 260 or a local controller can transmit a signal for the carriage 246 to move such that the die bonding sites of the bonding substrate 548 are under their corresponding dies within the set of dies 722 as illustrated in FIG. 10.

The method can further include modulating the set of dies while being held by die chucks of the array of bonding heads at block 522 in FIG. 5. Data can be useful in determining how much pressurization should be used for modulating the set of dies 722. The modulation can take a form of bowing the set of dies 722. For example, as a die occupies a larger area (X-direction and Y-direction dimensions) and is thinner (Z-direction dimension), less pressure is needed to bow the die as compared to a die that occupies a smaller area, is thicker, or both. If the die is attached to a backing plate, the combined thickness of the die and backing plate can be used when determining the pressure to achieve a desired amount of bowing. The thicknesses of the dies alone or the combinations of dies and their corresponding backing plates can be in a range from 20 microns to 800 microns or from 20 microns to 300 microns. The methods described herein are well suited for thicknesses of at most 100 microns. The data can be obtained for many different die areas and thicknesses. The memory 262 or a table or database external to the die bonding apparatus 201 can have data that correlates different areas and thicknesses of the die and the positive pressures or ranges of positive pressures to use to allow for sufficient bowing of the dies. The information can be empirical data collected before using the data in production.

Referring to FIGS. 3 and 11, the controller 260 or a local controller transmits a signal for a pressure actuator to be activated and allow a pressurized gas to increase the pressure within the flow channel 839 and the zone 869. A pressure sensor can sense the pressure within the flow channel 839 and transmit a signal to the controller 260 or the local controller, so that the controller 260 or the local controller can control the pressure to be at or within acceptable tolerance of a desired pressure. The activities described with respect to the particular die 822 in FIGS. 11 to 15. The activities also apply to the other dies within the set of dies 722 that will be bonding to the die bonding sites of the bonding substrate 548.

As the pressure within the zone 869 increases, the particular die 822 in FIG. 11 is modulated by bowing away the particular die 822 from the die chuck 2244 within the array of bonding heads 224 and toward the base 240 or the bonding substrate 548 that is coupled to the base 240 (seen in FIG. 10). The other dies within the set of dies 722 can have a bowed shape similar to the particular die 822 illustrated in FIG. 11. In another implementation, modulating the particular die 822 can be performed by modulating the die chuck 2244 on which the particular die 822 is held or modulating the particular die 822 itself. The modulating may be performed with air pressure or mechanical pressure.

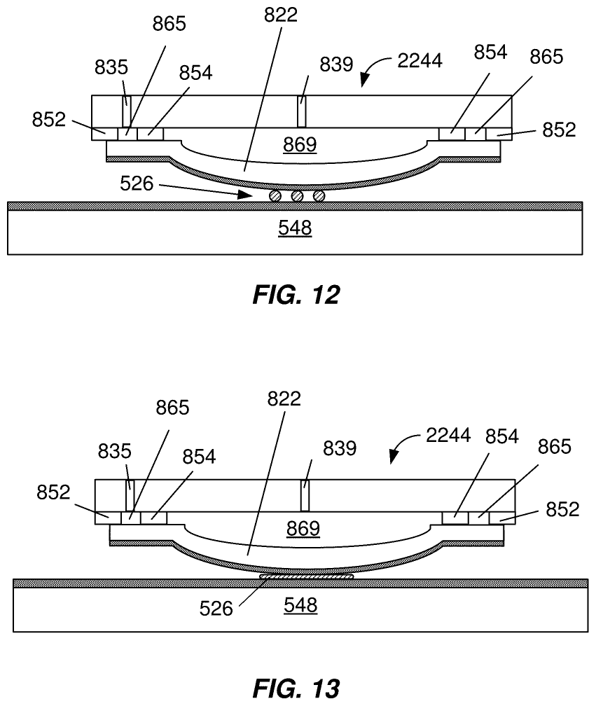

The method can include bringing the set of dies and the liquid on the bonding substrate in contact while the dies are modulated at block 542 in FIG. 5, wherein bringing the set of dies and the liquid in contact can be performed in series or in parallel. Referring to FIGS. 3 and 12, the bonding heads within the array of bonding heads 224 can be extended toward the bonding substrate 548, the substrate chuck 248 can be extended toward the array of bonding heads 224, or both.

As illustrated in FIG. 12, the center of the particular die 822 can initially contact the droplets of the liquid 526. As the distance between the particular die 822 and the bonding substrate decreases, the liquid 526 spreads out to form a film of liquid 526 in FIG. 13. The droplets may coalesce as illustrated in FIG. 13 or may not coalesce (not illustrated). The presence of the liquid, regardless whether in the form of droplets or a film, helps to reduce errors related to alignment, distortion, or both. In particular, vibration and other noise within the die bonding apparatus 201 may cause unintended movement of the set of dies 722 and the bonding substrate 548 relative to each other and contribute to alignment error between bonding pads within the set of dies 722 and corresponding bonding sites within the die bonding sites of the bonding substrate 548. The liquid 526 can help to provide a damping function with respect to the vibration or other noise. Further, the liquid 526 can help to delay physical contact until further demodulation of the dies within the set of dies 722 occurs. Thus, the distortion seen in FIG. 1, where no liquid is present between the die and bonding substrate, may be obviated or substantially reduced.

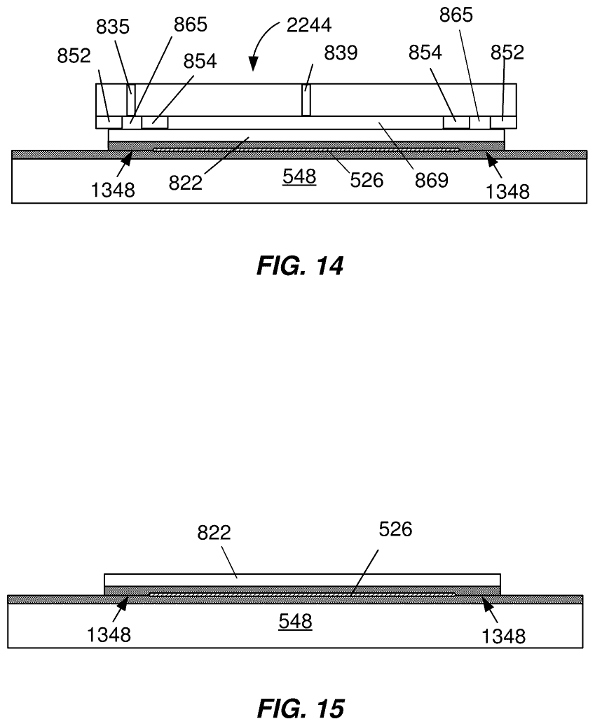

The method can further include applying a force to the set of dies such that the liquid is in contact with part, and not all, of the dies within the set of dies at block 544 and demodulating the set of dies such that an outer region of the die contacts the die bonding sites at block 546 in FIG. 5. Referring to FIGS. 13 and 14, as the particular die 822 is brought closer to the bonding substrate 548, the liquid 526 can become starved allowing one or more of the corners of the particular die 822 to physically contact the activated surface at the die bonding site of the bonding substrate 548. As illustrated in FIG. 14, the liquid 526 does not reach the peripheral edge of the particular die 822, and the outer region of the particular die 822 contacts the corresponding die bonding site of the bonding substrate 548 at locations 1348. Thus, demodulating can be performed such that the liquid 526 is not present where an outer region of the particular die 822 overlaps and contacts the die bonding site of the bonding substrate 548. A portion of the liquid 526 can underlap the center of the die when the outer region of the particular die 822 is in contact with the die bonding site.

In other terms, during die bonding, the liquid 526 spreads starting from close to the center of the die outward but eventually stops spreading when the liquid 526 thickness gets too thin. At a certain point, as the thickness of the liquid 526 is sufficiently thin, the shear stress increases and slows down the spreading front velocity of the liquid 526 while the velocity of the die-to-die bonding site conforming front during demodulation is greater than the liquid spreading velocity. Such a velocity difference can cause the boundary of the die-to-die bonding site contact at locations, such as closer corners of the die as compared to the center of the die, to be starved of the liquid 526. Even if the liquid is a Newtonian fluid at a macroscopic level, as the liquid 526 becomes starved, the liquid 526 can exhibit non-Newtonian behavior. In an implementation, when the thickness of the liquid is approximately 10 nm or less, the liquid 526 may behave like a solid, and the liquid 526 no longer flows. As demodulation of the particular die 822 continues, the particular die 822 contacts the corresponding die bonding site of the bonding substrate 548 at locations 1348.

Pressure can be exerted to bond the set of dies 722 to corresponding bonding sites of the bonding substrate 548. In an implementation illustrated in FIG. 14, the bonds can be oxide-to-oxide bonds between the particular die 822 and its corresponding die bonding site of the bonding substrate 548 initially at the locations 1348. The force during bonding can be at least 20 N. In an implementation, regarding pressure, the pressure during bonding can be in a range from 0.5 N/cm² to 20 N/cm². The controller 260 or a local controller can transmit a signal for a motor, hydraulic pressure, or another mechanical component that can be used to drive the array of bonding heads 224, the substrate chuck 248, or both in the Z-direction to achieve the bonding pressure.

Referring to FIG. 14, during bonding, if needed or desired, the pressure within the zone 869 can be at a positive pressure that is at or within a tolerance of the pressures exerted by the motor, the hydraulic pressure, or other mechanical component to allow for more uniform pressure along the surface of the set of dies 722, including the particular die 822 illustrated in FIG. 14, during bonding. In another implementation, the pressure within the zone 869 can be at or near ambient pressure. In the same or different implementation, the pressure within the zone 865 can remain at vacuum pressure, be at or near ambient pressure, or a pressure that is substantially the same as within the zone 869.

The bonding can be performed at room temperature (for example, at a temperature in a range from 20° C. to 25° C.) or higher. Bonding is performed at a temperature less than a subsequent anneal to expand conductive metal within the dies and at the die bonding sites. The temperature may be limited depending on films present during bonding or components within the die bonding apparatus 201. For example, the temperature may be no higher than approximately 200° C. After reading this specification, skilled artisans will be able to determine the pressure and temperature used for bonding.

The particular die 822 can be released from the die chuck 2244. Referring to FIGS. 3 14, and 15, the controller 260 or a local controller transmits a signal for pressure actuators to be activated and allow the flow channel 835, the zone 865, the flow channel 839, and zone 869 to reach atmospheric pressure or a pressure slightly higher than atmospheric pressure, for example, 0.1 N/cm². A pressure sensor can sense the pressure within the flow channels 835 and 839 and transmit a signal to the controller 260 or the local controller, so that the controller 260 or the local controller can control the pressure to be atmospheric pressure or slightly above. After the pressure is at or close to ambient pressure, the die chuck 2244 can be decoupled from the particular die 822.

The controller 260 or a local controller can transmit a signal for the bonding heads within the array of bonding heads 224 to be moved away from the bonding substrate 548, the substrate chuck 248 to be moved away the array of bonding heads 224, or both. FIG. 15 includes an illustration after the die chuck 2244 and the particular die 822 are moved away from each other.

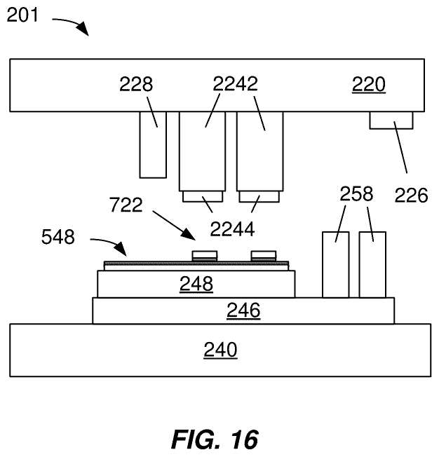

FIG. 16 includes a cross-sectional view of the die bonding apparatus 201 after the set of dies 722 is bonded to corresponding die bonding sites of the bonding substrate 548. At this point in the method, one transfer cycle has been completed.

A determination is made whether more dies are to be transferred from the source substrate to the bonding substrate at decision diamond 566 in FIG. 5. If more dies are to be transferred (“YES” branch), the method continues starting at block 444 in FIG. 4 with a next set of dies to be transferred during another transfer cycle. The method can be iterated as many times as needed for the bonding substrate 548 to have a desired number of dies. If no more dies are to be transferred (“NO” branch from decision diamond 566 in FIG. 5), the transfer operation is completed.

After all of the transfer cycles have been performed and the transfer operation is completed, the bonding substrate 548 and the corresponding bonded dies can be annealed at a temperature in a range from 180° C. to 400° C. In an implementation, annealing may be performed at one or more temperatures. As the temperature of the conductive metal increases, the conductive metal expands. The conductive metal in electrical components within the bonding substrate 548 contacts the conductive metal in the bonded dies to make a physical and electrical coupling between the conductive materials. If needed or desired, the anneal temperature can be increased further, so that atoms from the conductive metals can cross the interfaces between the electrical components in the bonding substrate 548 and the bonded dies and reduce contact resistance. In an implementation, the physical and electrical coupling can be a physical and electrical connection. Thus, the bonded dies and the sets of electrical components in the bonding substrate 548 can allow voltages to be passed and current to flow between the bonded dies and the sets of electrical components in the bonding substrate 548. The bonding substrate 548 can be removed from the die bonding apparatus 201 or moved to a different portion of the die bonding apparatus 201 or a different tool to perform the anneal operations.

The method can further include performing one or more post-bonding operations at block 582 in FIG. 5. Non-limiting examples can include electrical testing the electronic devices that includes the bonded dies, dicing the bonding substrate into individual electronic devices, cleaning the electronic devices, packaging the electronic devices, or performing another suitable post-bonding operation. The order in which the post-bonding operations may or may not depend on the particular electronic devices. For example, the packaging operation may be performed before or after the dicing operation is performed. Still further, more than one electrical test may be performed at different times where an intervening operation may or may not be performed between the electrical tests. For example, a first electrical test for electrical shorts or electrical opens may be performed before packaging. After packaging, a second electrical test can be performed to test a memory to ensure data can be written and retrieved or a processor to ensure instructions can be performed properly. At this point in the method, devices have been made.

A method of manufacturing an electronic device can include any of the methods previously described. The workpiece including the bonding substrate 548 and the set of dies 722 and potentially other dies can be further processed to form substantially completed electronic devices, wherein any one or more of the electronic devices can include an electrical circuit element, an optical element, a microelectromechanical system (MEMS), a recording element, a sensor, a mold, an integrated circuit, a power transistor, a charge coupled-device (CCD), an image sensor, a microfluidic device, or another electronic component. The integrated circuit may be a solid state memory (such as a dynamic random access memory (DRAM), a static random access memory (SRAM), a flash memory, and a magnetoresistive memory (MRAM)), a microprocessor, a microcontroller, a graphics processing unit, a digital signal processor, a field programmable gate array (FPGA) or a semiconductor element, or a die including a plurality of circuits.

In a finished electronic device, the liquid 526 may not be present between the dies and the corresponding die bonding sites of the bonding substrate 548. In an implementation, the liquid 526 can dissipate within porosity of one or more layers at or near the bonding interface within the dies, the bonding substrate 548, or both the dies and the bonding substrate 548. In another implementation, one or more drain lines may be within the dies, the bonding substrate 548, or both the dies and the bonding substrate 548.

Many different benefits may be seen in different implementations of the concepts described herein. The implementations have at least one benefit described herein but not all benefits are required to be seen in all implementations.

A die can be bonded to a bonding substrate while a liquid is present between the die and the bonding substrate. The liquid can help dampen vibration or other noise that may interfere with alignment between the die and its corresponding die bonding site of the bonding substrate. The amount of liquid and its location on the die bonding site can be selected such that the liquid is starved during demodulation of the die so that an outer region of the die, such as one or more corners of the die, physically contacts the die bonding site when bonding the die to the die bonding site. The amount of distortion between the die and its corresponding die bonding site can be substantially less than if no liquid would have been present.

The inventor has found that a continuous liquid film that extends beyond the die edges interferes with the ability to stably align the die to the bonding substrate with high level accuracy required. The inventor has also found that adhesives interfere with the electrical and thermal performance of the final device after bonding. The problems seen with a continuous liquid under all of the die during bonding and the adhesive can be obviated by using the methods described herein.

Note that not all of the activities described above in the general description or the examples are required, that a portion of a specific activity may not be required, and that at least one further activity can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of systems and apparatuses that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method, comprising:
dispensing a liquid onto a die bonding site of a substrate;
modulating a die held by a die chuck such that the die bonding site is closer to a center of the die than a peripheral edge of the die;
bringing the die into contact with the liquid, while the peripheral edge of the die is not in contact with the die bonding site; and
demodulating the die such that an outer region of the die is brought into contact with the die bonding site such that the liquid is not present where the outer region overlaps and contacts the die bonding site.

2. The method of claim 1, wherein, along a major surface of the die, the peripheral edge of the die includes at least two edges.

3. The method of claim 1, wherein the outer region includes a corner of the die.

4. The method of claim 1, wherein bringing the die into contact with the liquid causes a film to form that has a film area less than an area of the die.

5. The method of claim 1, wherein the liquid does not include an adhesive compound.

6. The method of claim 1, wherein the liquid includes water, an alkyl alcohol having at most three carbon atoms, or a mixture of the water and the alkyl alcohol.

7. The method of claim 1, wherein:
$${volume}_{liq} = film area * thickness , \qquad ( Equation 1 )$$
volume_{liq} is a volume of the liquid dispensed,
film area is in a range from 50% to 75% of an area of a major surface of the die, and
thickness is in a range from 5 nm to 10 nm.

8. The method of claim 1, wherein demodulating the die is performed such that the outer region of the die is brought into contact with the die bonding site, and a portion of the liquid underlaps the center of the die when the outer region is in contact with the die bonding site.

9. A method, comprising:
dispensing a liquid onto a die bonding site of a substrate, wherein the liquid is a Newtonian fluid;
modulating a die held by a die chuck such that the die bonding site is closer to a center of the die than a peripheral edge of the die;
bringing the die into contact with the liquid, while the peripheral edge of the die is not in contact with the die bonding site; and
demodulating the die, wherein, during at least a portion of demodulating the die, at least a portion of the liquid exhibits non-Newtonian behavior.

10. The method of claim 9, wherein during initial contact of the die with the liquid, the liquid exhibits Newtonian behavior.

11. The method of claim 9, wherein during demodulating, at least a portion of the liquid between the die and the die bonding site has a thickness of at most 5 nm.

12. The method of claim 9, wherein the liquid includes water, an alkyl alcohol having at most three carbon atoms, or a mixture of the water and the alkyl alcohol.

13. The method of claim 9, wherein the liquid does not contact at least one corner of the die during dispensing the liquid, modulating the die, and demodulating the die.

14. The method of claim 9, where demodulating the die is performed such that the outer region of the die is brought into contact with the die bonding site, and a portion of the liquid underlaps the center of the die when the outer region is in contact with the die bonding site.

15. A method, comprising:
dispensing a liquid onto a die bonding site of a substrate;
modulating a die held by a die chuck such that the die bonding site is closer to a center of the die than a peripheral edge of the die;
bringing the die into contact with the liquid, wherein bringing the die into contact with the liquid causes a film to form; and
demodulating the die such that at least a portion of the film becomes starved and does not flow to an outer region of the die.

16. The method of claim 15, wherein:
$${volume}_{liq} = area * thickness , \qquad ( Equation 1 )$$
volume_{liq} is a volume of the liquid dispensed,
area is in a range from 50% to 75% of a major surface of the die, and
thickness is in a range from 5 nm to 10 nm.

17. The method of claim 15, wherein the liquid includes water, an alkyl alcohol having at most three carbon atoms, or a mixture of the water and the alkyl alcohol.

18. The method of claim 15, wherein demodulating the die is performed such that at least a portion of the peripheral edge of the of the die is brought into contact with the die bonding site, and a portion of the liquid underlaps the center of the die when the outer region is in contact with the die bonding site.

19. A system, comprising:
a liquid dispense head; and
a die chuck,
wherein the system is adapted to:
dispense a liquid from the liquid dispense head onto a die bonding site of a substrate;
modulate a die held by the die chuck such that the die bonding site is closer to a center of the die than a peripheral edge of the die;
bring the die into contact with the liquid, while the peripheral edge of the die is not in contact with the die bonding site; and
demodulate the die such that an outer region of the die is brought into contact with the die bonding site such that the liquid is not present where the outer region overlaps and contacts the die bonding site.

20. A method of manufacturing a plurality of electronic devices, comprising:
dispensing a liquid onto die bonding sites of a substrate;
modulating dies held by die chucks such that the die bonding sites are closer to centers of the dies than peripheral edges of the dies;
bringing the dies into contact with the liquid, while the peripheral edges of the dies are not in contact with the die bonding sites;
demodulating the dies such that outer regions of the dies are brought into contact with the die bonding sites such that the liquid is not present where the outer regions overlap and contact the die bonding sites; and
dicing the substrate to form individual electron devices, wherein dicing is performed after demodulating the dies.
